(19) United States
(12) Patent Application Publication
(10) Pub. No.: US 2003/0181031 A1
(43) Pub. Date: Sep. 25, 2003

(54) Method for manufacturing a semiconductor device

(75) Inventors: Akihiro Kojima, Yokohama-shi (JP); Tokuhisa Ohiwa, Kawasaki-shi (JP); Hisataka Hayashi, Yokohama-shi (JP)

Correspondence Address: Finnegan, Henderson, Farabow,, Garrett & Dunner, L.L.P., 1300 I Street, N.W., Washington, DC, 20005-3315, US

(73) Assignee: KABUSHIKI KAISHA TOSHIBA

(21) Appl. No.: 10/286,812

(22) Filed: Nov. 4, 2002

(30) Foreign Application Priority Data
Mar. 25, 2002 (JP) 2002-084511

(51) Int. Cl. H01L 21/44; H01L 21/4763

(52) U.S. Cl. 438/627; 438/637; 438/653

(57) ABSTRACT

Disclosed is a method for manufacturing a semiconductor device comprising forming, above a semiconductor substrate on which elements are formed, a wiring layer with a metal nitride film on its surface, forming an insulating film on the wiring layer, forming a mask pattern on the insulating film, forming a via hole in the insulating film by reactive ion etching using the mask pattern as an etching mask, thereby exposing the metal nitride film, removing the mask pattern, and performing plasma treatment of a surface of the metal nitride film using a nitrogen-containing gas.

### CROSS-REFERENCE TO RELATED APPLICATIONS

This application is based upon and claims the benefit of priority from the prior Japanese Patent Application No. 2002-84511, filed Mar. 25, 2002, the entire contents of which are incorporated herein by reference.

### BACKGROUND OF THE INVENTION

1. Field of the Invention

The present invention relates to a method for manufacturing a semiconductor device, and more particularly to a method for manufacturing a semiconductor device having a multilayer wiring structure, in which a metal nitride film is formed on a wiring.

2. Description of the Related Art

With enhancement of integration and increase in operation speed of semiconductor devices, the wiring resistance and the capacitance between wirings are required to decrease. For this purpose, it is imperative to expedite the decrease in dielectric constant of an interlayer insulating film, resistance of a metal wiring and contact resistance. In recent years, aluminum (Al) or copper (Cu) is used as a wiring material of a multilayer wiring structure. Such a structure includes a barrier metal layer to prevent the metal from diffusing into an insulating film.

Particularly, in the case where a barrier metal layer containing a metal nitride, such as titanium nitride (TiN), is formed on a lower metal wiring, the surface of the barrier metal layer must be kept clean in order to maintain low contact resistance and the reliability thereof. When a via hole is formed in an interlayer insulating film to connect an upper wiring and a lower metal wiring having the barrier metal layer thereon, reactive ion etching (RIE) is employed in general. Perfluoro-compound (PFC) mixture gas, such as C₄F₈/CO/Ar or CHF₃/CO/O₂ gas, is used in the RIE. The gas causes deposition of a fluorocarbon film and oxidation of the metal nitride film on the surface of the barrier metal layer. To form a clean contact interface, it is necessary to remove the deposited film and the oxidized metal nitride.

In order to remove the deposited film and the oxidized metal nitride on the surface of the barrier metal film, wet treatment, ashing treatment, etc. are considered. However, either treatment cannot completely prevent oxidation of the surface of the barrier metal layer. Particularly, in the ashing treatment, the substrate to be processed is exposed to a gas containing oxygen at a high temperature of 150° C. to 250° C. Therefore, the surface of the barrier metal layer is further oxidized.

If the oxidized metal nitride is removed from the surface of the barrier metal film by sputtering, dielectric breakdown may occur in elements formed on the semiconductor substrate due to charging damage. In the case of a barrier metal layer formed of TiN, if a Ti film is formed on an oxidized surface, the oxidized TiN can be reduced but the oxide cannot be completely removed. In either case, the reliability of the device is lowered.

### BRIEF SUMMARY OF THE INVENTION

A method for manufacturing a semiconductor device according to one embodiment of the present invention comprises:

forming, above a semiconductor substrate on which elements are formed, a wiring layer with a metal nitride film on its surface;

forming an insulating film on the wiring layer;

forming a mask pattern on the insulating film;

forming a via hole in the insulating film by reactive ion etching using the mask pattern as an etching mask, thereby exposing the metal nitride film;

removing the mask pattern; and

performing plasma treatment of a surface of the metal nitride film using a nitrogen-containing gas.

A method for manufacturing a semiconductor device according to another embodiment of the present invention comprises:

forming, above a semiconductor substrate on which elements are formed, a wiring layer with a metal nitride film on its surface;

forming an insulating film on the wiring layer;

forming a via hole in the insulating film by reactive ion etching, thereby exposing the metal nitride film;

ashing in a state where the metal nitride film is exposed; and

performing plasma treatment of a surface of the metal nitride film using a nitrogen-containing gas.

### BRIEF DESCRIPTION OF THE SEVERAL VIEWS OF THE DRAWING

FIGS. 1A to 1D are cross-sectional views showing steps of a method for manufacturing a semiconductor device according to an embodiment of the present invention;

FIG. 2 is a cross-sectional view showing an interlayer structure formed by the method according to the embodiment; and

FIGS. 3A and 3B are cross-sectional views showing a conventional method for manufacturing a semiconductor device.

### DETAILED DESCRIPTION OF THE INVENTION

An embodiment of the present invention will be described in detail with reference to the accompanying drawings.

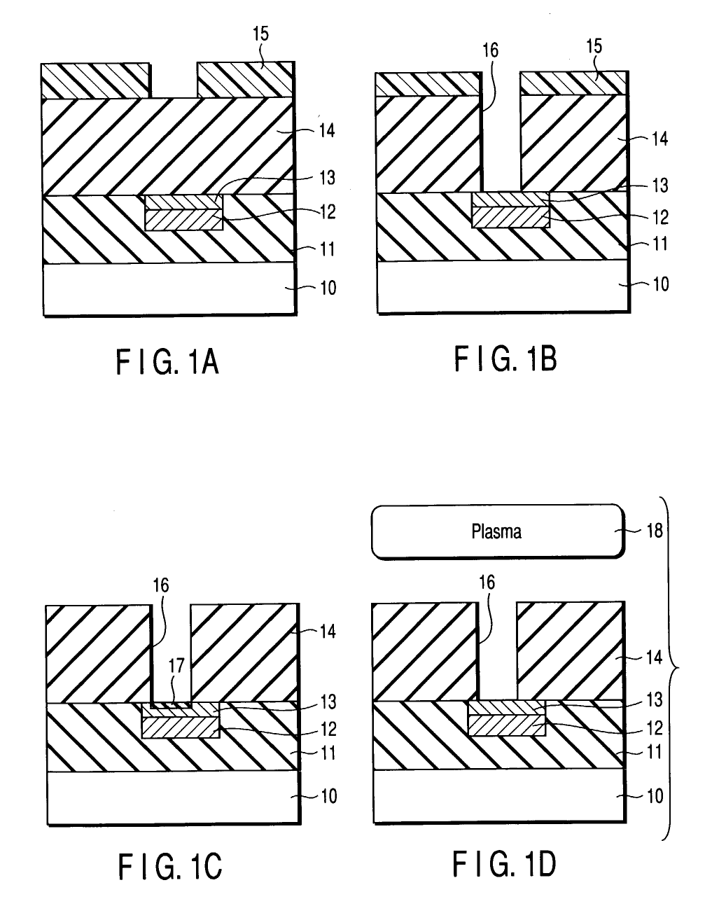

FIGS. 1A to 1D are cross-sectional views showing steps of a method for manufacturing a semiconductor device according to an embodiment of the present invention.

First, as shown in FIG. 1A, an insulating film 11, in which a lower wiring layer 12 is buried, is formed on a semiconductor substrate 10. An insulating film 14 is formed on the insulating film 11. Elements (not shown) are formed in advance on the semiconductor substrate 10, which has a diameter of 8 inches. The lower wiring layer 12 may be formed of Al or Cu. To prevent the metal from diffusing into the insulating film 14, thereby improving the reliability, the lower wiring layer 12 includes a metal nitride film 13 in the surface thereof. The metal nitride film 13, serving as a barrier metal layer, is formed of TiN in this embodiment. It is possible to use a metal nitride containing at least one selected from the group consisting of Cr, Co, Y, Zr, Mo, Ta, Hf, W and Ir. The insulating films 11 and 14 may be silicon oxide films formed by, for example, CVD.

A mask pattern 15 is formed on the insulating film 14 by photolithography, as shown in FIG. 1A. The mask pattern 15 may be formed of an organic material, such as resist.

The insulating film 14 is processed by reactive ion etching (RIE) using a C₄F₈/CO/Ar/O₂ mixture gas series with the mask pattern 15 as an etching mask. As a result, the metal nitride film 13 is exposed and a via hole 16 connected to the lower wiring layer 12 is formed in the insulating film 14, as shown in FIG. 1B. At this time, the etching selectivity of the insulating film (silicon oxide film) 14 to TiN, which forms the metal nitride film 13, is 30 to 45.

Through the RIE using the aforementioned mixture gas, a fluorocarbon film is deposited on the surface of the metal nitride film 13, and TiN in the surface of the metal nitride film 13 is oxidized (not shown).

Then, oxygen plasma treatment is carried out by an ashing apparatus, which is controlled to an oxygen flow rate of 9000 sccm, a discharge pressure of 2.0 Torr, and a substrate temperature of 250° C. As a result, the mask pattern 15 is removed, as shown in FIG. 1C. The mask pattern 15 can be removed by plasma treatment using a gas containing at least one selected from the group consisting of O₂, CO, CO₂, NO, NO₂ and H₂O. Although the fluorocarbon film deposited on the surface of the metal nitride film 13 is removed along with the mask pattern 15, an oxidized metal nitride 17 occurs in the surface of the metal nitride film 13.

According to the method of this embodiment, the oxidized metal nitride 17 is nitrided by reduction through the treatment with plasma 18 using a gas containing nitrogen, as shown in FIG. 1D. The nitrogen-containing gas can be selected from the group consisting of NH₃ gas, N₂ gas and N₂/H₂ mixture gas. It is desirable that the gas contain substantially no oxygen. More specifically, it is preferable that the oxygen content of the nitrogen-containing gas be 0.1% by volume or less. The content of N₂ to the mixture gas is not particularly limited. Even if the amount of N₂ is very little, the surface of the oxidized metal nitride film 13 can be nitrided by the reduction function of N₂.

To carry out the plasma treatment, first, the semiconductor substrate 10 with the metal nitride film 13 having an oxidized surface was introduced in a vacuumed chamber. The semiconductor substrate 10 was placed on a sample table, to which a high-frequency power of 13.56 MHz is applicable. The semiconductor substrate was kept at 25° C. to 20° C. by a cooling mechanism provided on the sample table. Then, ammonia gas, as a nitrogen-containing gas, was introduced in the chamber at 200 sccm and the pressure in the chamber was kept at 200 mTorr, and the high-frequency power of 500W was applied. Under these conditions, the surface of the metal nitride film 13 was exposed to ammonia plasma for 60 seconds.

The aforementioned plasma treatment using the nitrogen-containing gas reduces the oxidized metal nitride in the surface of the metal nitride film 13, so that the metal nitride contains substantially no oxygen. Since the surface of the metal nitride film 13 is cleaned, the wiring resistance does not increase and the reliability does not lower. Moreover, when a metal wiring is formed, the burying characteristic does not deteriorate.

The plasma treatment is not limited to the above conditions in particular, but can be carried out under normal conditions. The conditions can be suitably set within the ranges of, for example, a flow rate of the nitrogen-containing gas: about 200 to 300 sccm, a pressure in the chamber: about 100 to 500 mTorr, a high-frequency power: about 300 to 500W (1.0 to 1.6 W/cm²), and a treatment time: 60 to 120 seconds.

It is particularly preferable that the plasma treatment is performed while RF is applied to a side of the semiconductor substrate. In this case, the nitriding of the surface is enhanced by the influence of ion energy.

After the cleaning step, Ti/TiN or Nb, as a barrier metal to prevent a wiring material Al from diffusing into the insulating film, and Al, as a wiring material to be connected to an upper layer wiring, were deposited on the overall surface of the insulating film 14 by sputtering. Then, an excess metal portion was planarized by CMP, with the result that a via plug 19 having a barrier metal layer on the side and bottom surfaces thereof was formed in the via hole 16. Thus, an interlayer structure corresponding to one layer was obtained.

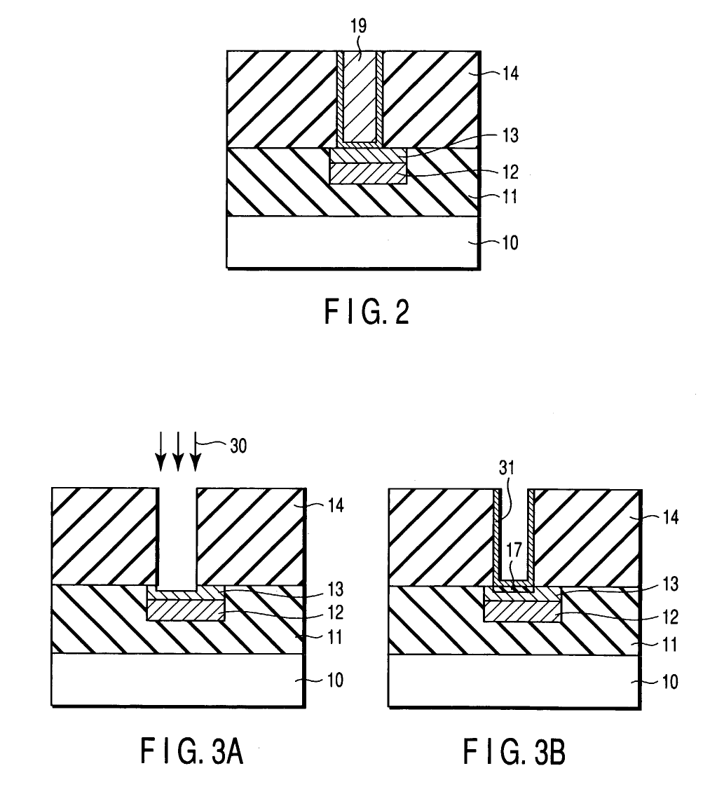

Since the surface of the metal nitride film 13 of the interlayer structure shown in FIG. 2 is nitrided by the plasma treatment using a nitrogen-containing gas, a portion of the film 13 on the interface with the via plug 19 contains very little oxygen. More specifically, the oxygen content of the portion of the barrier metal layer 13 on the interface with the via plug 19 does not exceed the detection limit by AES (Auger Electron Spectroscopy) analysis, i.e., 1.0 atomic % or less.

According to the conventional method, the oxidized metal nitride 17 in the surface of the metal nitride film 13 is physically removed by sputtering with Ar gas 30, as shown in FIG. 3A. In this case, electrical damages to elements are caused by plasma, resulting in decrease of the breakdown voltage of an insulating film between wirings or layers and a gate insulating film formed in the lower layer. Accordingly, dielectric breakdown due to charging damage may occur.

Alternatively, according to the conventional method, if the metal nitride film 13 is formed of TiN, a Ti film 31 is formed on the oxidized metal nitride 17, as shown in FIG. 3B, so that the oxygen density in the surface can be decreased, thereby practically lowering the electric resistance. In this case, since the portion containing oxygen remains in the surface of the metal nitride film 13, the electric resistance cannot be fully lowered. More specifically, oxygen at 2 to 3 atomic % remain in the surface of the metal nitride film 13. This causes deterioration of the EM/SM resistance, and may lower the reliability owing to the increase in contact resistance.

In the method of the embodiment of the present invention, as described above, the surface of the oxidized nitride film 17 is nitrided by reduction through the plasma treatment using a nitrogen-containing gas. In other words, the oxidized metal nitride is replenished with nitrogen, thereby forming a barrier metal layer comprising a metal nitride containing substantially no oxygen; the oxygen content is equal to or less than the detection limit by AES analysis. Thus, since the surface of the metal nitride film 13 is cleaned without electrical damages, all inconveniences caused by the conventional method can be eliminated.

Even if the oxide on the surface of the metal film is reduced by plasma treatment using a nitrogen-containing gas, the surface may be easily re-oxidized, since the film obtained after the reduction may not be a nitride film but a metal film. Therefore, in general, to avoid re-oxidation, the metal film surface is continuously subjected to a next step after the reduction so as not to break the atmosphere, for example, the vacuum.

On the other hand, according to the embodiment of the present invention, a metal nitride film containing substantially no oxygen is formed through the plasma treatment. Therefore, even if the substrate is taken out of the treatment chamber in the next step, the metal film is not easily oxidized naturally. Accordingly, the subsequent step need not be performed continuously, and the process conditions can be changed arbitrarily.

With the method according to the embodiment of the present invention, even if metal and nitrogen lack in balance and nitrogen in the metal nitride film is decreased, the nitrogen deficit can be compensated for. For example, when a metal nitride film such as a TiN film, formed by sputtering or MOCVD, is damaged, nitrogen in the film may decrease. The metal nitride film with decreased nitrogen can be replenished with nitrogen by plasma treatment with a nitrogen-containing gas as described above. As a result, a high-quality metal nitride film can be formed.

The present invention is not limited to the above embodiment, which has, for example, a damascene structure. The same effect as described above can be obtained through the plasma treatment using a nitrogen-containing gas in any wiring structure having a metal nitride film on its surface. For example, if an Al wiring is formed by RIE using a Ti/TiN film as an antireflection film, a metal nitride film exists on the Al wiring. Such a metal nitride film is oxidized when a via hole is formed in an insulating film formed thereon. The oxidized metal nitride film can be nitrided by the treatment according to the embodiment of the present invention. If a metal nitride film, containing at least one selected from the group consisting of Cr, Co, Y, Zr, Mo, Ta, Hf, W and Ir, is formed on a lower wiring, the surface of the film may be oxidized when a via hole is formed, as in the case of TiN film. In this case, the surface of the metal nitride film can also be cleaned through the plasma treatment using a nitrogen-containing gas without an electrical damage.

As has been described above, according to the embodiment of the present invention, there is provided a method for manufacturing a reliable semiconductor device having a multilayer wiring structure, in which a metal nitride film is formed on a wiring.

The present invention is very effectively applicable to manufacturing a semiconductor device having a multilayer wiring structure in which a metal nitride is used as a barrier metal layer on a wiring, and has great industrial significance.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A method for manufacturing a semiconductor device comprising:
forming, above a semiconductor substrate on which elements are formed, a wiring layer with a metal nitride film on its surface;
forming an insulating film on said wiring layer;
forming a mask pattern on said insulating film;
forming a via hole in said insulating film by reactive ion etching using said mask pattern as an etching mask, thereby exposing said metal nitride film;
removing said mask pattern; and
performing plasma treatment of a surface of said metal nitride film using a nitrogen-containing gas.

2. The method according to claim 1, wherein said metal nitride film contains at least one metal selected from the group consisting of Ti, Cr, Co, Y, Zr, Mo, Ta, Hf, W and Ir.

3. The method according to claim 1, wherein said wiring layer contains one of Cu and Al.

4. The method according to claim 1, wherein said mask pattern is made of an organic material.

5. The method according to claim 1, wherein said removing said mask pattern is performed by plasma treatment using a gas containing at least one selected from the group consisting Of O₂, CO, CO₂, NO, NO₂ and H₂O.

6. The method according to claim 1, wherein said nitrogen-containing gas is at least one selected from the group consisting of NH₃ gas, N₂ gas and N₂/H₂ mixture gas.

7. The method according to claim 1, wherein a surface of said metal nitride film is oxidized by said removing the mask pattern, and nitrided by said plasma treatment using the nitrogen-containing gas.

8. The method according to claim 1, wherein oxygen content of said nitrogen-containing gas is at most 0.1% by volume.

9. The method according to claim 1, wherein said plasma treatment using said nitrogen-containing gas is carried out while RF is applied to a side of said semiconductor substrate.

10. The method according to claim 1, further comprising:
depositing a conductive film in said via hole to form a via plug, said depositing a conducive film being carried out after said semiconductor substrate is taken out of a treatment chamber in which said plasma treatment using said nitrogen-containing gas was carried out.

11. A method for manufacturing a semiconductor device comprising:
forming, above a semiconductor substrate on which elements are formed, a wiring layer with a metal nitride film on its surface;
forming an insulating film on said wiring layer;
forming a via hole in said insulating film by reactive ion etching, thereby exposing said metal nitride film;
ashing in a state where said metal nitride film is exposed; and
performing plasma treatment of a surface of said metal nitride film using a nitrogen-containing gas.

12. The method according to claim 11, wherein said metal nitride film contains at least one metal selected from the group consisting of Ti, Cr, Co, Y, Zr, Mo, Ta, Hf, W and Ir.

13. The method according to claim 11, wherein said wiring layer contains one of Cu and Al.

14. The method according to claim 11, wherein said ashing removes deposits generated by said reactive ion etching and deposited on said metal nitride film.

15. The method according to claim 11, wherein said ashing is plasma treatment using a gas containing at least one selected from the group consisting of O₂, CO, CO₂, NO, NO₂ and H₂O.

16. The method according to claim 11, wherein said nitrogen-containing gas is at least one selected from the group consisting of NH₃ gas, N₂ gas and N₂/H₂ mixture gas.

17. The method according to claim 11, wherein a surface of said metal nitride film is oxidized by said ashing, and nitrided by said plasma treatment using the nitrogen-containing gas.

18. The method according to claim 11, wherein oxygen content of said nitrogen-containing gas is at most 0.1% by volume.

19. The method according to claim 11, wherein the plasma treatment using said nitrogen-containing gas is carried out while RF is applied to a side of said semiconductor substrate.

20. The method according to claim 11, further comprising:
depositing a conductive film in said via hole to form a via plug, said depositing a conducive film being carried out after said semiconductor substrate is taken out of a treatment chamber in which said plasma treatment using said nitrogen-containing gas was carried out.
